(19) United States
(12) Patent Application Publication
(10) Pub. No.: US 2014/0162453 A1
(43) Pub. Date: Jun. 12, 2014

(54) SEMICONDUCTOR DEVICE AND METHOD FOR FABRICATING THE SAME

(71) Applicant: SK hynix Inc., Gyeonggi-do (KR)

(72) Inventors: Sung-Kwon LEE, Gyeonggi-do (KR); Jun-Hyeub SUN, Gyeonggi-do (KR); Su-Young KIM, Gyeonggi-do (KR); Jong-Sik BANG, Gyeonggi-do (KR)

(73) Assignee: SK hynix Inc., Gyeonggi-do (KR)

(21) Appl. No.: 14/181,192

(22) Filed: Feb. 14, 2014

Related U.S. Application Data
(62) Division of application No. 13/334,031, filed on Dec. 21, 2011.

(30) Foreign Application Priority Data
Aug. 10, 2011 (KR) 10-2011-0079565

(51) Int. Cl. H01L 21/768

(52) U.S. Cl. CPC H01L 21/76897
USPC 438/675

(57) ABSTRACT

A semiconductor device that may prevent an unexposed substrate and generation of bowing profile during a process for forming an open region having a high aspect ratio, and a method for fabricating the semiconductor device. The semiconductor device includes a first material layer formed over a substrate, an open region formed in the first material layer that exposes the first material layer, a second material layer formed on sidewalls of the open region, wherein the second material layer is a compound material including an element of the first material layer, and a conductive layer formed inside the open region.

### CROSS-REFERENCE TO RELATED APPLICATIONS

The present application claims priority of Korean Patent Application No. 10-2011-0079565, filed on Aug. 10, 2011, which is incorporated herein by reference in its entirety,

### BACKGROUND

1. Field

Exemplary embodiments of the present invention relate to a semiconductor device fabrication method, and more particularly, to a semiconductor device including an open region with a high aspect ratio and a method for fabricating the same.

2. Description of the Related Art

As semiconductor devices become highly integrated, a process for forming an open region having a high aspect ratio, such as storage node holes or metal contact plugs, for example, MIC, may be difficult.

FIGS. 1A to 1C are cross-sectional views illustrating an exemplary conventional method for forming an open region of a semiconductor device. FIGS. 2A and 2B are cross-sectional views illustrating features of the conventional technology.

Referring to FIG. 1A, a mold layer 12 and a hard mask pattern 13 are sequentially formed over a substrate 11 where a structure is already formed.

Referring to FIG. 1B, storage node contact holes 15 are formed by etching the mold layer 12 until the substrate 11 is exposed using the hard mask pattern 13 as an etch barrier. When the etch process for forming the storage node contact holes 15 is performed, a polymer layer 14 is deposited on the sidewalls of each storage node contact hole 15 to form a vertical sidewall profile as soon as the etch process is performed.

Referring to FIG. 1C, a cleaning process is performed to remove the polymer layer 14 that is generated while forming the storage node contact holes 15.

Forming a vertical sidewall profile in an open region having a high aspect ratio, such as the storage node contact holes 15 shown in FIG. 1C, may cause issues in the conventional technology. To form the vertical sidewall profile in each open region having a high aspect ratio, the etch process for forming the storage node contact holes 15 is performed so that the polymer layer 14 is deposited on the sidewalls of each storage node contact hole 15 as soon as the etch process is performed.

However, as the storage node contact holes 15 are formed deeper into the mold layer 12, it becomes more difficult to deposit the polymer layer 14 on the sidewalls in the deeper portions of each open region due to an etch loading phenomenon. Therefore, a bowing profile is generated in the lower portion of each storage node contact hole 15 (refer to a reference symbol ‘A’ of FIG. 2A). To prevent the etch loading phenomenon, the etch process may increase the deposition thickness of the polymer layer. However, if the etch process is performed to increase the deposition thickness of the polymer layer 14 as the storage node contact holes 15, the etch rate may be decreased or the storage nodes contact holes 15 may not expose the substrate 11 (refer to a reference symbol ‘B’ of FIG. 2B). The above issues are more evident as the depth of the storage node contact holes 15 is increased and/or the linewidth is decreased.

### SUMMARY

An embodiment of the present invention is directed to a semiconductor device that may prevent a not-open problem and generation of bowing profile during a process for forming an open region having a high aspect ratio, and a method for fabricating the semiconductor device.

In accordance with an embodiment of the present invention, a semiconductor device includes: a first material layer formed over a substrate; an open region formed in the first material layer that exposes the first material layer; a second material layer formed on sidewalls of the open region, wherein the second material layer is a compound material including an element of the first material layer; and a conductive layer formed inside the open region.

In accordance with another embodiment of the present invention, a method for fabricating a semiconductor device includes: forming a first material layer over a substrate; forming a hard mask pattern over the first material layer; forming a first pattern by using the hard mask pattern as an etch barrier and etching a portion of the first material layer; forming a second material layer on a surface of the first pattern through a surface treatment; forming a second pattern by using the hard mask pattern as an etch barrier and etching the first material layer under the first pattern until the substrate is exposed; and forming a conductive layer inside an open region that is formed of the first pattern and the second pattern.

In accordance with yet another embodiment of the present invention, a method for fabricating a semiconductor device includes: forming a first material layer over a substrate; forming a hard mask pattern over the first material layer; forming a first pattern by using the hard mask pattern as an etch barrier and etching a portion of the first material layer and simultaneously forming a first polymer layer on sidewalls of the first pattern; removing the first polymer layer; forming a second material layer on a surface of the first pattern through a surface treatment; forming a second pattern by using the hard mask pattern as an etch barrier and etching the first material layer under the first pattern until the substrate is exposed and simultaneously forming a second polymer layer on sidewalls of the first pattern and the second pattern; and forming a conductive layer inside an open region that is formed of the first pattern and the second pattern.

### BRIEF DESCRIPTION OF THE DRAWINGS

FIGS. 1A to 1C are cross-sectional views illustrating a conventional method for forming an open region of a semiconductor device.

FIGS. 2A and 2B are cross-sectional views illustrating exemplary outcomes from the processes of the conventional technology.

FIGS. 3A to 3F are cross-sectional views illustrating a method for forming an open region of a semiconductor device in accordance with an embodiment of the present invention.

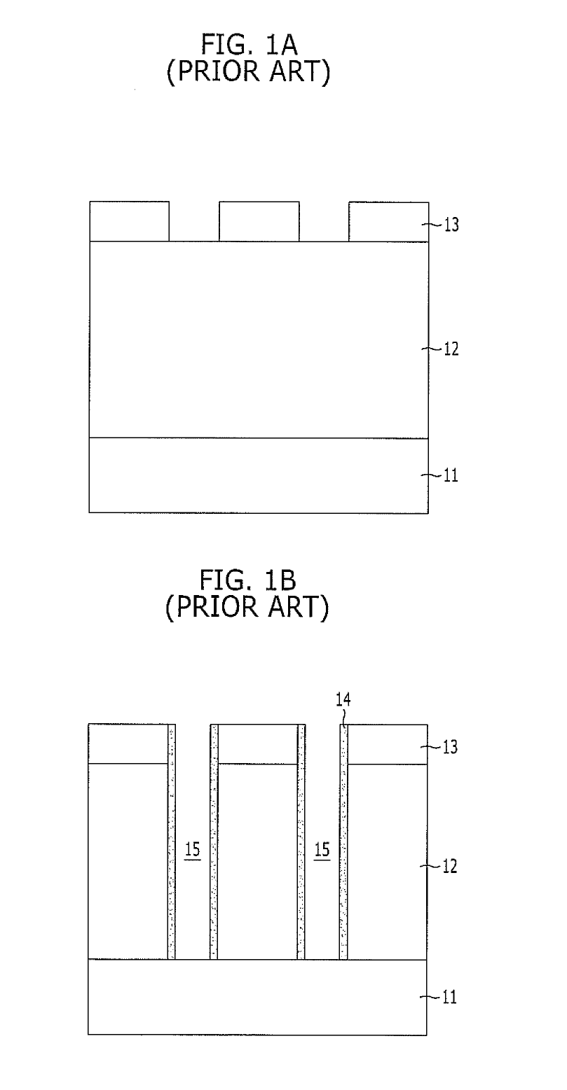

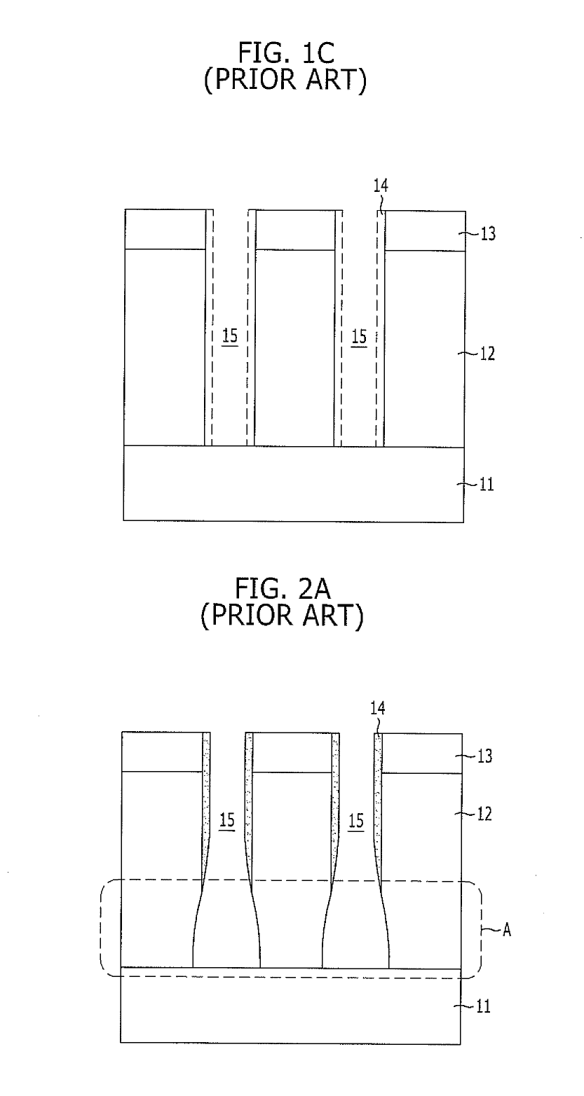

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

An embodiment of the present invention provides a semiconductor device that may prevent an unexposed substrate and a bowing profile during a process for forming an open region having a high aspect ratio, such as storage node holes and metal contact plugs, for example, M1C, and a method for fabricating the semiconductor device. The following embodiment of the present invention describes a method for forming storage node holes to illustrate an embodiment of the present invention.

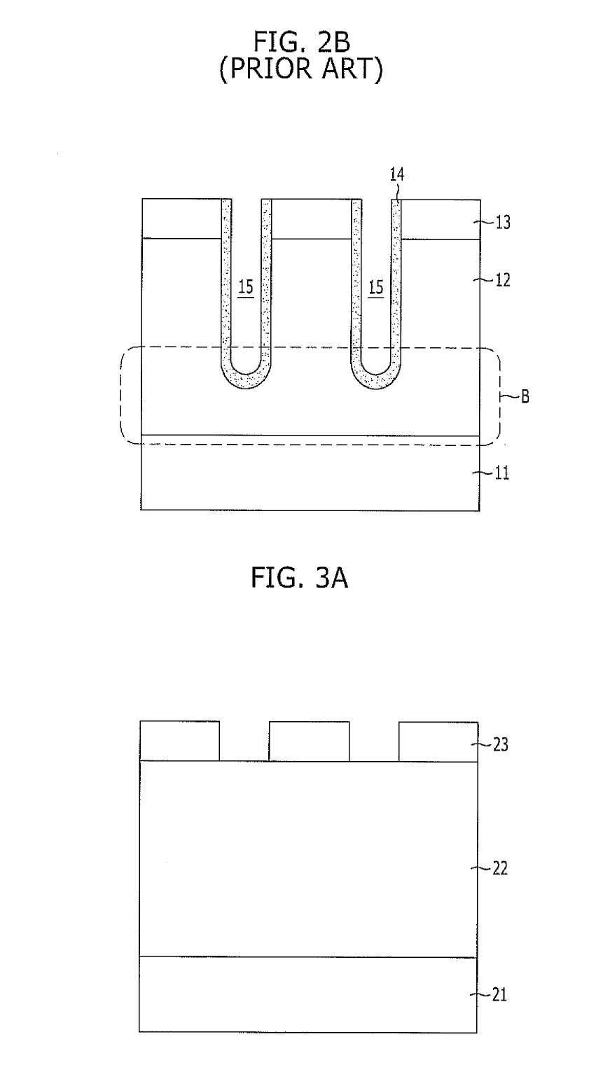

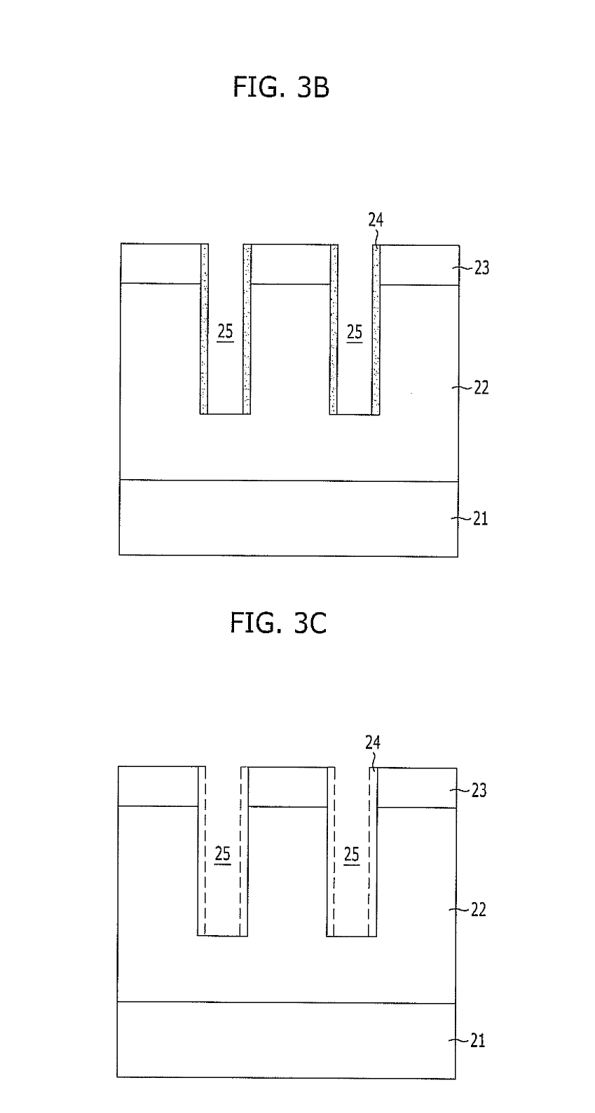

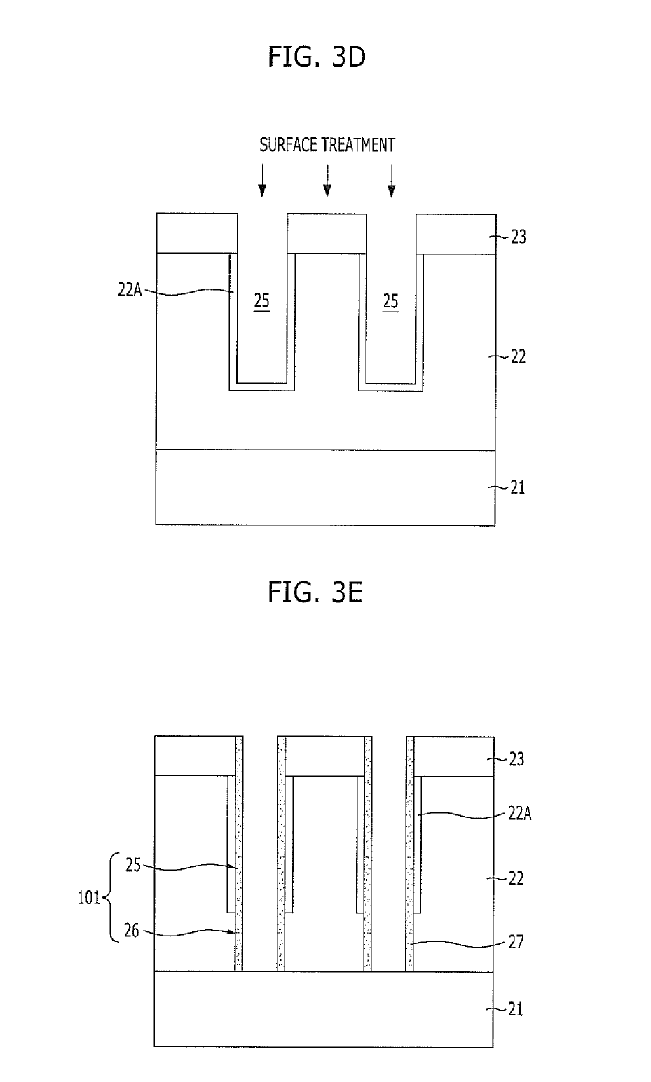

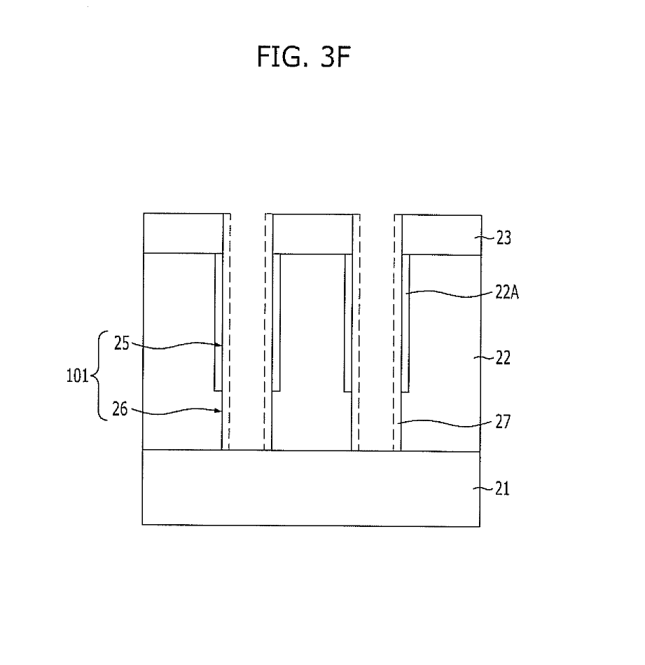

FIGS. 3A to 3F are cross-sectional views illustrating a method for forming an open region of a semiconductor device in accordance with an embodiment of the present invention.

Referring to FIG. 3A, a first material layer 22 is formed over a substrate 21. An existing structure, such as transistors, word lines, bit lines, and so forth may have already been formed in the substrate 21. The first material layer 22 may be a mold layer. The first material layer 22 may be formed of a material that may transform into a second material through a subsequent surface treatment. The first material layer 22 may also have an etch selectivity with respect to the second material layer that is generated through the subsequent surface treatment. More specifically, the first material layer 22 may be a semiconductor layer. For example, the first material layer 22 may be formed of silicon (Si), and the silicon used for the first material layer 22 may be polycrystalline silicon or amorphous silicon.

When the first material layer 22 functions as a mold layer and is formed as an insulation layer, it may be difficult to form a single first material layer 22 that is thick enough for the desired features of the semiconductor device. Therefore, a method of stacking a plurality of insulation layers may be used. Although the first material layer 22 may be formed by a plurality of stacking insulation layers of the same base material, there may be complications in an etch process that forms the open regions. In particular, the sidewall profile may not be controlled and may not be formed properly. However, when the first material layer 22 is formed of a semiconductor layer, for example, a silicon layer, as illustrated in the first embodiment of the present invention, the first material layer 22 may be a single silicon layer that fulfills the desired thickness of the first material layer. Since the first material layer 22 may be formed in a single layer, the etch process and forming the sidewall profile may be performed without the issues described above. Moreover, since the semiconductor layer may be deposited quickly and at a low temperature, the existing structure formed in the substrate 21 before the deposition of the first material layer 22 may secure thermal stability, and a semiconductor device may be more productive.

Subsequently, a hard mask pattern 23 is formed over the first material layer 22. The hard mask pattern 23 may be formed of a material selected from the group consisting of an oxide layer, a nitride layer, an oxynitride layer, and a carbon-containing layer, or a stacked layer thereof.

Referring to FIG. 3B, a first etch process is performed that etches a portion of the first material layer 22 by using the hard mask pattern 23 as an etch barrier. The etch process creates a first pattern 25 as part of the process to form open regions. The first pattern 25 is formed to have a depth that does not etch to the surface of the substrate 21 and to a depth where an etch loading phenomenon does not occur. The etch loading phenomenon may occur when the first material layer 22 is etched to a depth closer to the surface of the substrate 21.

The first etch process may be performed through a dry etch process. The first etch process deposits a first polymer layer 24 on the sidewalls of the first pattern 25 and etches the first material layer 22 simultaneously. The first polymer layer 24 that is formed on the sidewalls of the first pattern 25 forms a vertical sidewall profile. The first polymer layer 24 protects the sidewalls of the first pattern 25 during the etch process for forming the first pattern 25. To form the first pattern 25, the etch process may be performed using a gas mixture comprising a gas for generating a polymer as soon as the first material layer 22 is etched and a gas that controls the thickness of the first polymer layer 24 that is deposited on the sidewalls of the first pattern 25. More specifically, when the first material layer 22 is a silicon layer, the etch process that forms the first pattern 25 may be performed using a mixed gas (HBr/NF₃/O₂) of hydrogen bromide (HBr) gas, nitrogen trifluoride (NF₃) gas, and oxygen (O₂) gas. Hydrogen bromide (HBr) gas is used to generate the first polymer layer 24 as soon as the first material layer 22 is etched, and the nitrogen trifluoride (NF₃) gas and oxygen (O₂) gas are used to etch the first polymer layer 24 and thereby control the thickness of the first polymer layer 24 on the sidewalls of the first pattern 25. Also, oxygen (O₂) gas improves the etch selectivity between the hard mask pattern 23 and the first material layer 22.

Referring to FIG. 3C, after the etch process for forming the first pattern 25 ends, a cleaning process is performed to remove the first polymer layer 24. The first polymer layer 24 may be removed through a dry cleaning process or a wet cleaning process. The dry cleaning process may be carried out using a gas mixture of nitrogen trifluoride (NF₃) gas and oxygen (O₂) gas. The wet cleaning process may be performed using a mixed solution (NH₄OH/H₂O₂/H₂O) of ammonium hydroxide (NH₄OH), hydrogen peroxide (H₂O₂), and deionized water (H₂O; DI) or a mixed solution (H₂SO₄/H₂O₂/H₂O) of sulfuric acid (H₂SO₄), hydrogen peroxide (H₂O₂), and deionized water (H₂O; DI).

The first polymer layer 24 remaining on the sidewalls of the first pattern 25 is removed by the cleaning process in order to prevent the internal linewidth of the first pattern 25 from decreasing and to prevent an etch loading phenomenon from occurring during a subsequent process that further etches the first material layer 22. In other words, the cleaning process is performed to prevent a bowing profile from being formed in the lower portion of each open region due to the etch loading phenomenon that occurs as the depth of the open region increases, or as the aspect ratio of the open region increases.

Referring to FIG. 3D, a surface treatment is performed to form a second material layer 22A on the surface of the first pattern 25. The second material layer 22A may be formed as the surface of the first material layer 22 is transformed through the surface treatment. The second material layer 22A is a material that has an etch selectivity with respect to the first material layer 22. The surface treatment is performed to prevent the internal linewidth of the first pattern 25 from decreasing due to the formation of the second material layer 22A.

The surface treatment may be an oxidation, nitration, or oxynitrocarburising surface treatment. The oxidation, nitration or oxynitrocarburising may be performed through a thermal treatment, plasma treatment, radical treatment, or a combination thereof. For example, the surface treatment may be performed by a thermal treatment, plasma treatment, radical treatment alone, or the surface treatment may be performed by simultaneously performing, for example, thermal treatment and plasma treatment.

When the first material layer 22 is a silicon layer, the second material layer 22A formed on the surface of the first pattern 25 may be one selected from the group consisting of a silicon oxide layer, a silicon nitride layer, and a silicon oxynitride layer. The second material layer 22A formed on the surface of the first pattern 25 is formed to a uniform thickness along the surface of the first pattern 25. The second material layer 22A has a uniform thickness because a reactant for the surface treatment is uniformly provided in the form of a gas state, an ion state, or a radical state to the surface of the substrate structure where the first pattern 25 is formed.

Referring to FIG. 3E, a second etch process is performed to further etch the first material layer 22 using the hard mask pattern 23 as an etch barrier. The first material layer is etched under the first pattern 25 during the second etch process. During the second etch process, the second material layer 22A formed at the bottom surface of the first pattern 25 is also etched because of the directivity of the second etch process, which is an anisotropic etch process. The second etch process, however, does not affect the pattern profile. Hereafter, the pattern formed under the first pattern 25 through the second etch process is referred to as a second pattern 26.

The second etch process may be performed through a dry etch process. The second etch process deposits a second polymer layer 27 on the sidewalls of the first pattern 25 and the second pattern 26 to form a vertical sidewall profile and etch the first material layer 22 simultaneously. To form the second pattern 26, the etch process may be performed using a gas mixture for generating a polymer as soon as the first material layer 22 is etched. The etch process may also use a gas mixture that controls the thickness of the second polymer layer 27 that is deposited on the sidewalls of the first pattern 25 and the second pattern 26. More specifically, when the first material layer 22 is a silicon layer, the etch process that forms the second pattern 26 may be performed using a mixed gas (HBr/NF₃/O₂) of hydrogen bromide (HBr) gas, nitrogen trifluoride (NF₃) gas, and oxygen (O₂) gas. Hydrogen bromide (HBr) gas is used to generate the second polymer layer 27 as soon as the first material layer 22 is etched, and the nitrogen trifluoride (NF₃) gas and oxygen (O₂) gas are used to etch the second polymer layer 27 and thereby control the thickness of the second polymer layer 27 on the sidewalls of the second pattern 26. Also, oxygen (O₂) gas improves the etch selectivity between the hard mask pattern 23 and the first material layer 22.

The second material layer 22A prevents the internal linewidth of the first pattern 25 from decreasing while protecting the sidewalls of the first pattern 25 simultaneously. Therefore, the second polymer layer 27 forms on the sidewalls of the second pattern 26 during the etch process that forms the second pattern 26. Also, the second polymer layer 27 prevents the substrate from being unexposed in the open regions 101.

Through the above described process, open regions 101 formed of the first pattern 25 and the second pattern 26 may be formed. The second material layer 22A remains on the sidewalls of the first pattern 25 when the etch process for forming the second pattern 26 ends. Although the embodiment of the present invention illustrates that the open regions 101 are formed by performing a first etch process, a surface treatment, and a second etch process, the open regions 101 may be formed by repeatedly performing the first etch process, the surface treatment, and the second etch process in a cycle according to the aspect ratio of the open regions 101 and until the substrate 11 is exposed.

Referring to FIG. 3F, after the etch process that forms the second pattern 26 ends, a cleaning process is performed to remove the second polymer layer 27 on the sidewalls of the second pattern 26. The second polymer layer 27 may be removed through a dry cleaning process or a wet cleaning process. The dry cleaning process may be carried out using a gas mixture of nitrogen trifluoride (NF₃) gas and oxygen (O₂) gas. The wet cleaning process may be performed using a mixed solution (NH₄OH/H₂O₂/H₂O) of ammonium hydroxide (NH₄OH), hydrogen peroxide (H₂O₂), and deionized water (H₂O; DI) or a mixed solution (H₂SO₄/H₂O₂/H₂O) of sulfuric acid (H₂SO₄), hydrogen peroxide (H₂O₂), and deionized water (H₂O; DI).

Subsequently, although not illustrated in the figures, after the open regions 101 are formed, the hard mask pattern 23 is removed, and a conductive layer is formed in the inside of the open regions 101. For example, the conductive layer may form storage nodes. The storage nodes may be formed in a cylindrical shape, a concave shape, or a pillar shape.

Alternatively, the open regions 101 may be formed to be contact holes for metal contact plugs, for example, M1C. Metal contact plugs having a high aspect ratio may be formed through a series of processes that form insulation spacers on the sidewalls of the open regions 101 and subsequently gap-fill the inside of the open regions 101 with a conductive material. According to another embodiment of the present invention, plugs having a high aspect ratio may be formed by gap-filling the inside of the open regions 101 with a conductive material without forming the insulation spacers so as to form the plugs having a high aspect ratio This embodiment also includes the processes of removing the first material layer 22 and the second material layer 22A, and forming an insulation layer covering the plugs over the substrate 11, and performing a planarization process until the upper surface of the plugs are exposed.

The semiconductor device fabricated in accordance with an embodiment of the present invention may include the first material layer 22 formed over the substrate 11, the open regions 101 that expose the substrate 11 through the first material layer 22, the second material layer 22A formed on the sidewalls of the open regions 101 by performing a surface treatment onto the first material layer 22, and the conductive layer, which is storage nodes or plugs, formed in the inside of the open regions 101. Since the open regions 101 having a high aspect ratio may be formed by forming the second material layer 22A through an etch process and a surface treatment that are performed onto the first material layer 22 through several steps, the reliability of the semiconductor device may be improved. Also, the open regions do not have the bowing profile or an unexposed substrate.

While the present invention has been described with respect to the specific embodiments, it will be apparent to those skilled in the art that various changes and modifications may be made without departing from the spirit and scope of the invention as defined in the following claims.

1-5. (canceled)

6. A method for fabricating a semiconductor device, comprising:
forming a first material layer over a substrate;
forming a hard mask pattern over the first material layer;
forming a first pattern by using the hard mask pattern as an etch barrier and etching a portion of the first material layer;
forming a second material layer on a surface of the first pattern by performing a surface treatment to the first material layer;
forming a second pattern by using the hard mask pattern as an etch barrier and etching the first material layer under the first pattern until the substrate is exposed; and
forming a conductive layer inside an open region that is formed of the first pattern and the second pattern.

7. The method of claim 6, wherein the second material layer has an etch selectivity to the first material layer, and the second material layer is formed by transforming the first material layer through the surface treatment.

8. The method of claim 7, wherein the first material layer comprises a silicon layer, and the second material layer comprises a silicon insulation layer.

9. The method of claim 6, wherein the surface treatment is performed through one method selected from the group consisting of oxidation, nitration, and oxynitrocarburising.

10. The method of claim 9, wherein the surface treatment is performed through one method selected from the group consisting of thermal treatment, plasma treatment, radical treatment, and a combination thereof.

11. The method of claim 6, wherein the conductive layer comprises storage nodes.

12. The method of claim 6, wherein the conductive layer comprises plugs, and further comprising:
forming insulation spacers on sidewalls of the open region before the plugs are formed.

13. The method of claim 6, wherein the conductive layer comprises plugs, and further comprising:
removing the first material layer and the second material layer after the conductive layer is formed; and
forming an insulation layer for gap-filling a space where the first material layer and the second material layer are removed.

14. A method for fabricating a semiconductor device, comprising:
forming a first material layer over a substrate;
forming a hard mask pattern over the first material layer;
forming a first pattern by using the hard mask pattern as an etch barrier and etching a portion of the first material layer and simultaneously forming a first polymer layer on sidewalls of the first pattern;
removing the first polymer layer;
forming a second material layer on a surface of the first pattern by performing a surface treatment to the first material layer;
forming a second pattern by using the hard mask pattern as an etch barrier and etching the first material layer under the first pattern until the substrate is exposed and simultaneously forming a second polymer layer on sidewalls of the first pattern and the second pattern; and
forming a conductive layer inside an open region that is formed of the first pattern and the second pattern.

15. The method of claim 14, wherein the second material layer has an etch selectivity to the first material layer, and the second material layer is formed by transforming the first material layer through the surface treatment.

16. The method of claim 15, wherein the first material layer comprises a silicon layer, and the second material layer comprises a silicon insulation layer.

17. The method of claim 14, wherein the forming of the first pattern and the first polymer layer and the forming of the second pattern and the second polymer layer are performed using a gas mixture comprising a gas that generates a polymer as soon as the first material layer is etched and a gas that etches the generated polymer.

18. The method of claim 17, wherein the gas that generates the polymer in etching the first material layer comprises hydrogen bromide (HBr) gas.

19. The method of claim 17, wherein the gas that etches the generated polymer comprises a mixed gas of nitrogen trifluoride (NF3) gas and oxygen (O2) gas.

20. The method of claim 14, wherein the surface treatment is performed through one method selected from the group consisting of oxidation, nitration, and oxynitrocarburising.

21. The method of claim 20, wherein the surface treatment is performed through one method selected from the group consisting of thermal treatment, plasma treatment, radical treatment, and a combination thereof.

22. The method of claim 14, wherein the conductive layer comprises storage nodes, and further comprising:
removing the first material layer and the second material layer after the conductive layer is formed.

23. The method of claim 14, wherein the conductive layer comprises plugs, and further comprising:
forming insulation spacers on sidewalls of the open region before the plugs are formed.

24. The method of claim 14, wherein the conductive layer comprises plugs, and further comprising:
removing the first material layer and the second material layer after the conductive layer is formed; and
forming an insulation layer for gap-filling a space where the first material layer and the second material layer are removed.

25. The method of claim 14, wherein the first material layer is formed as a single layer.
